(19) United States
(12) Patent Application Publication
(10) Pub. No.: US 2026/0144082 A1
(43) Pub. Date: May 21, 2026

(54) MANUFACTURING METHOD OF SEMICONDUCTOR PACKAGE

(71) Applicant: SK hynix Inc., Gyeonggi-do (KR)

(72) Inventors: Heon Yong CHANG, Gyeonggi-do (KR); Young Hun CHEONG, Gyeonggi-do (KR)

(21) Appl. No.: 19/086,076

(22) Filed: Mar. 20, 2025

(30) Foreign Application Priority Data
Nov. 15, 2024 (KR) 10-2024-0162611

(51) Int. Cl. H01L 23/00; H01L 21/48; H01L 25/065; H10B 80/00

(52) U.S. Cl. CPC H10W 70/05; H10W 90/00; H10B 80/00; H10W 72/01251; H10W 72/01255; H10W 72/01257; H10W 72/01935; H10W 72/07232; H10W 72/07252; H10W 72/221; H10W 72/227; H10W 72/252; H10W 72/255; H10W 72/952; H10W 72/953; H10W 90/722

(57) ABSTRACT

A manufacturing method of a semiconductor package including forming a through-electrode in a substrate including a first surface and a second surface opposite to each other, forming a front conductive bump on the first surface of the substrate, reflowing the front conductive bump, and planarizing an upper portion of the front conductive bump after reflowing the front conductive bump.

### CROSS-REFERENCE TO RELATED APPLICATION

The present application claims priority under 35 U.S.C. 119(a) to Korean patent application number 10-2024-0162611 filed on Nov. 15, 2024, which is incorporated herein by reference in its entirety.

### TECHNICAL FIELD

The embodiments of the present disclosure relate generally to semiconductor technology and, more particularly, relate to a manufacturing method of a semiconductor package.

### BACKGROUND

Technology for stacking semiconductor chips is being developed in response to the demand for higher integration of semiconductor packages. For example, for electrically connecting the stacked semiconductor chips a through-silicon-via (TSV) technology or a technology for bonding chips using bonding pads or solders may be used.

However, despite significant advancements in these technologies, the increasing demand for higher integration poses new challenges requiring more precise bonding and stacking of semiconductor chips. As a result, existing technologies for electrically connecting semiconductor chips are facing technological limitations and new solutions are needed.

### SUMMARY

Embodiments of the present disclosure are directed to a manufacturing method of a semiconductor package with improved electrical connection characteristics between semiconductor chips.

It should be noted that the embodiments of the present disclosure are not limited to the embodiments described in this specification, and other embodiments which are not specifically mentioned will be clearly understood by those skilled in the art from the following description.

Embodiments of the present disclosure are directed to a manufacturing method of a semiconductor package including forming a through-electrode in a substrate including a first surface and a second surface opposite to each other, forming a front conductive bump on the first surface of the substrate, reflowing the front conductive bump, and planarizing an upper portion of the front conductive bump after reflowing the front conductive bump.

Embodiments of the present disclosure are directed to a manufacturing method of a semiconductor package including forming a first front conductive bump on a first surface of a first semiconductor chip, the first semiconductor chip further including a second surface opposite to the first surface, reflowing the first front conductive bump, planarizing an upper portion of the first front conductive bump after reflowing the first front conductive bump, forming a second back conductive bump on a second surface of a second semiconductor chip including a first surface and the second surface opposed to each other and stacked below the first surface of the first semiconductor chip, and connecting the second back conductive bump to the first front conductive bump after planarizing the upper portion of the first front conductive bump.

Embodiments of the present disclosure are directed to a manufacturing method of a semiconductor package including providing a first semiconductor chip including first and second surfaces opposite to each other, providing a second semiconductor chip including first and second surfaces opposite to each other, forming a first front conductive bump on the first surface of the semiconductor chip, forming a second back conductive bump on the second surface of the second semiconductor chip, reflowing and planarizing the upper portion of the first front conductive bump and stacking the second semiconductor chip below the first surface of the first semiconductor chip so that the second back conductive bump contacts the first front conductive bump after planarizing the upper portion of the first front conductive bump.

According to embodiments of the present disclosure, there is provided a manufacturing method for making a semiconductor package with improved electrical connection characteristics between semiconductor chips that make the semiconductor package.

The effects of the embodiments of the present disclosure are not limited to the effects mentioned above, and other effects not mentioned will be understood by those skilled in the art from the description and the claims.

### BRIEF DESCRIPTION OF THE DRAWINGS

The embodiments of the present disclosure will be more fully understood from the detailed description and accompanying drawings provided below, which are provided for illustration only and are not intended to limit the embodiments to the described configurations of the figures.

FIG. 1 illustrates a cross-sectional structure of a semiconductor package according to embodiments of the present disclosure.

FIGS. 2 to 4 are enlarged drawings of 10 of FIG. 1.

FIGS. 5 to 23 are drawings illustrating a manufacturing method of a semiconductor package according to embodiments of the present disclosure.

FIGS. 24 to 27 are drawings illustrating a manufacturing method of a semiconductor package according to embodiments of the present disclosure.

### DETAILED DESCRIPTION

Hereinafter, embodiments of the present disclosure will be described in detail with reference to accompanying drawings. In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present disclosure, detailed descriptions of well-known functions and components incorporated herein will be omitted when it is determined that the description may make the subject matter in some embodiments of the present disclosure rather unclear. Terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the present invention. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes etc. are mentioned, it should be noted that numerical values for elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all meanings of the term “can”.

Hereinafter, it will be described various embodiments of the present disclosure in detail with reference to the accompanying drawings.

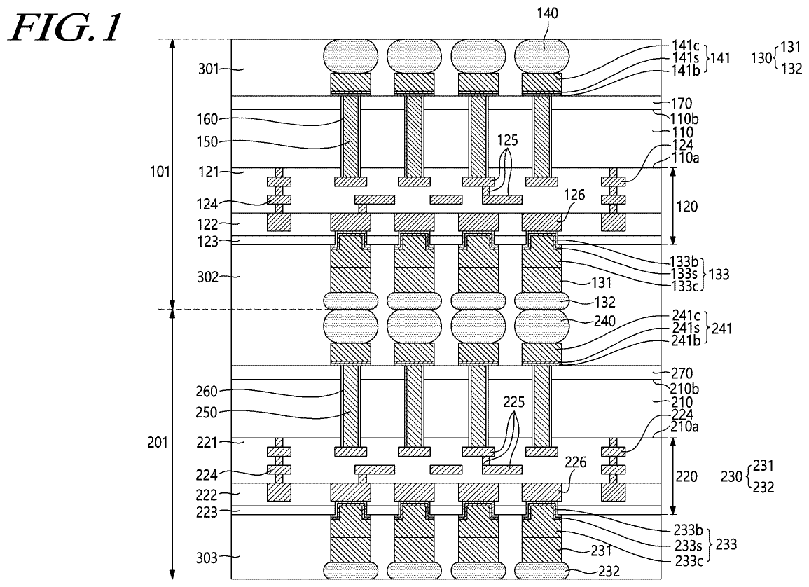

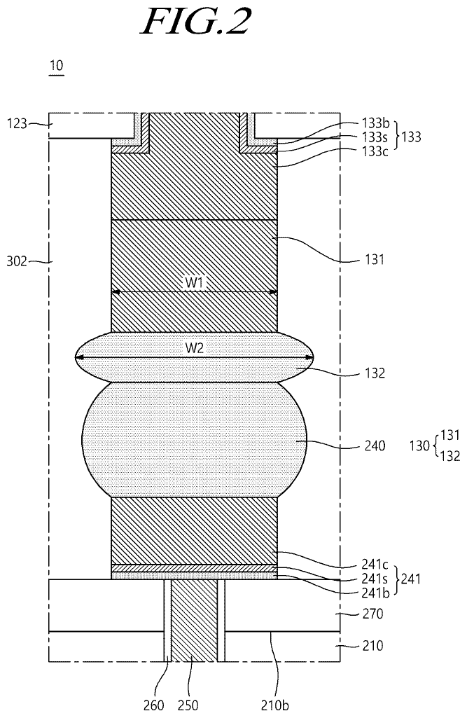

FIG. 1 illustrates a cross-sectional structure of a semiconductor package according to embodiments of the present disclosure, and FIGS. 2 to 4 are enlarged drawings of 10 of FIG. 1.

Referring to FIG. 1 and FIG. 2, a semiconductor package according to embodiments of the present disclosure may include a first semiconductor chip 101, a second semiconductor chip 201, and encapsulation layers 301, 302 and 303. The first semiconductor chip 101 may include a first substrate 110, a first wiring structure 120, a first through-electrode 150, a first spacer 160, a first front conductive bump 130, a first back conductive bump 140, and a first back insulating layer 170. The second semiconductor chip 201 may include a second substrate 210, a second wiring structure 220, a second through-electrode 250, a second spacer 260, a second front conductive bump 230, a second back conductive bump 240, and a second back insulating layer 270. The first wiring structure 120 and the second wiring structure 220 may include a guard ring 124.

The first substrate 110 may include a first surface 110a and a second surface 110b which are opposite to each other. The first surface 110a may be referred to as a front surface of the first substrate 110, and the second surface 110b may be referred to as a rear or back surface of the first substrate 110. Similarly, the second substrate 210 may include a first surface 210a and a second surface 210b that are opposite to each other. The first surface 210a may be referred to as a front surface of the second substrate 210, and the second surface 210b may be referred to as a rear or back surface of the second substrate 210.

The first wiring structure 120 may include a first circuit insulating layer 121, wirings 125, a guard ring 124, a chip pad 126, and a first protective insulating layer 122 and 123. The second wiring structure 220 may include a second circuit insulating layer 221, wirings 225, a guard ring 224, a chip pad 226, and a second protective insulating layer 222 and 223.

The first and second semiconductor chips 101 and 201 may further include various types of active/passive elements, such as transistors and/or capacitors, within the first and second substrates 110 and 210, between the first substrate 110 and the first wiring structure 120, between the second substrate 210 and the second wiring structure 220, or within the first and second wiring structures 120 and 220, but are omitted for the sake of brief description.

In an embodiment, the first and second semiconductor chips 101 and 201 may include a memory, a processor, or a combination thereof. The first and second semiconductor chips 101 and 201 may include a dynamic random access memory (DRAM), a static random access memory (SRAM), a flash memory, a magnetoresistive random access memory (MRAM), a phase-change random access memory (PRAM), a ferroelectric random access memory (FRAM), a resistive random access memory (PRAM), or a combination thereof.

The first wiring structure 120 may be disposed under the first surface 110a of the first substrate 110. A first through-electrode 150 may pass through the first substrate 110 in a vertical direction. The first through-electrode 150 may be connected to the first wiring structure 120. In an embodiment, one end of the first through-electrode 150 may enter inside the first circuit insulating layer 121 to contact the wirings 125.

A first front pad 133 may be arranged under the first wiring structure 120. The first front pad 133 may contact a lower surface of a first chip pad 126 in the first wiring structure 120. The first front pad 133 may be electrically connected to the wirings 125 through the first chip pad 126.

The first front conductive bump 130 may be connected under the first front pad 133. The first front conductive bump 130 may include a first bump pillar 131 and a first solder layer 132 connected to the first bump pillar 131. The first bump pillar 131 may be connected to the first front pad 133. The first solder layer 132 may be connected to the second back conductive bump 240 of the second semiconductor chip 201.

The first back insulating layer 170 may be disposed on the second surface 110b of the first substrate 110. A first back pad 141 may be disposed on the first back insulating layer 170 and the first through-electrode 150. The first through-electrode 150 may pass through the first back insulating layer 170, and may be connected to the first back pad 141. The first back conductive bump 140 may be disposed on the first back pad 141. The first back pad 141 may include a first back barrier layer 141b, a first back seed layer 141s, and a first back conductive layer 141c. The lower surface of the first back barrier layer 141b may contact the upper surface of the first through-electrode 150.

The encapsulation layers 301, 302 and 303 may include a first encapsulation layer 301, a second encapsulation layer 302, and a third encapsulation layer 303. The first encapsulation layer 301 may be disposed between the first semiconductor chip 101 and another semiconductor chip stacked on the first semiconductor chip 101. The second encapsulation layer 302 may be arranged between the first semiconductor chip 101 and the second semiconductor chip 201. The third encapsulation layer 303 may be arranged between the second semiconductor chip 201 and another semiconductor chip stacked below the second semiconductor chip 201.

The second wiring structure 220 may be disposed under the first surface 210a of the second substrate 210. A second through-electrode 250 may pass through the first substrate 210 in a vertical direction. The second through-electrode 250 may be connected to the second wiring structure 220. In an embodiment, one end of the second through-electrode 250 may pass through the second circuit insulating layer 221 and contact the wirings 225.

A second front pad 233 may be disposed under the second wiring structure 220. The second front pad 233 may contact a lower surface of the second chip pad 226 in the second wiring structure 220. The second front pad 233 may be electrically connected to the wirings 225 through the second chip pad 226.

The second front conductive bump 230 may be connected under the second front pad 233. The second front conductive bump 230 may include a second bump pillar 231 and a second solder layer 232 connected to the second bump pillar 231.

The second back insulating layer 270 may be disposed on the second surface 210b of the second substrate 210. A second back pad 241 may be disposed on the second back insulating layer 270 and the second through-electrode 250. The second through-electrode 250 may pass through the second back insulating layer 270, and may be connected to the second back pad 241. The second back conductive bump 240 may be disposed on the second back pad 241.

An upper surface of the second back conductive bump 240 may contact a lower surface of the first front conductive bump 130. A lower surface of the second front conductive bump 230 may contact an upper surface of the back conductive bump of the semiconductor chip located below the second semiconductor chip 201. The upper surface of the first back conductive bump 140 may contact an upper surface of a front conductive bump of the semiconductor chip positioned on the first semiconductor chip 101.

Referring to FIG. 2, the first front conductive bump 130 may be disposed under the first front pad 133. The first front conductive bump 130 may include a first bump pillar 131 and a first solder layer 132. The first front pad 133 may include a first front barrier layer 133b, a first front seed layer 133s, and a first front conductive layer 133c.

An upper surface of the first bump pillar 131 may contact a lower surface of the first front conductive layer 133c. A lower surface of the first bump pillar 131 may contact an upper surface of the first solder layer 132. The first solder layer 132 may be connected to the first bump pillar 131.

In an embodiment, a side surface of the first solder layer 132 may protrude further outward than a side surface of the first bump pillar 131. In an embodiment, the maximum width W2 of the first solder layer 132 may be greater than the width W1 of the first bump pillar 131. In an embodiment, the width of the first solder layer 132 may increase as it gets farther from the lower surface of the first bump pillar 131, and may decrease as it gets closer to the upper surface of the second back conductive bump 240. For example, the first solder layer 132 may have the maximum width W2 at the middle portion of the side surface of the first solder layer 132.

The second back conductive bump 240 may be connected to the first front conductive bump 130. An upper surface of the second back conductive bump 240 may contact a lower surface of the first solder layer 132. The second back conductive bump 240 may include the same material as the material forming the first solder layer 132.

The second back pad 241 may be connected under the second back conductive bump 240. The second back pad 241 may include a second back barrier layer 241b, a second back seed layer 241s, and a second back conductive layer 241c. The lower surface of the second back barrier layer 241b may contact the upper surface of the second through-electrode 250.

The second through-electrode 250 may pass through the second substrate 210 and the second back insulating layer 270 to contact the lower surface of the second back barrier layer 241b. The second spacer 260 may surround the side surface of the second through-contact 250.

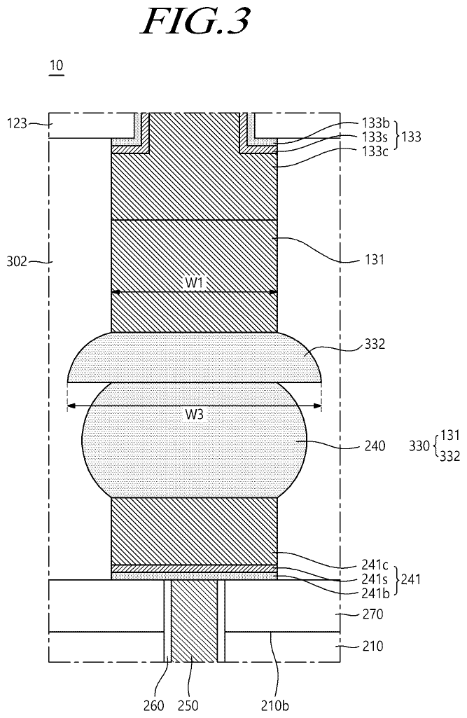

Referring to FIG. 3, a first front conductive bump 330 may be disposed under the first front pad 133. The first front conductive bump 330 may include a first bump pillar 131 and a first solder layer 332. The lower surface of the first bump pillar 131 may contact the upper surface of the first solder layer 332. The first solder layer 332 may be connected to the first bump pillar 131.

In an embodiment, the side surface of the first solder layer 332 may protrude further outward than the side surface of the first bump pillar 131. In an embodiment, the maximum width W3 of the first solder layer 332 may be greater than the width W1 of the first bump pillar 131. In an embodiment, the width of the first solder layer 332 may increase as it moves away from the upper surface of the first bump pillar 131. For example, the first solder layer 332 may have the maximum width W3 at a portion contacting the upper surface of the second back conductive bump 240.

The second back conductive bump 240 may be connected to the first front conductive bump 330. The upper surface of the second back conductive bump 240 may contact the lower surface of the first solder layer 332. In an embodiment, the width of the upper surface of the second back conductive bump 240 may be less than the width of the lower surface of the first solder layer 332. The second back conductive bump 240 may include the same material as the material forming the first solder layer 332.

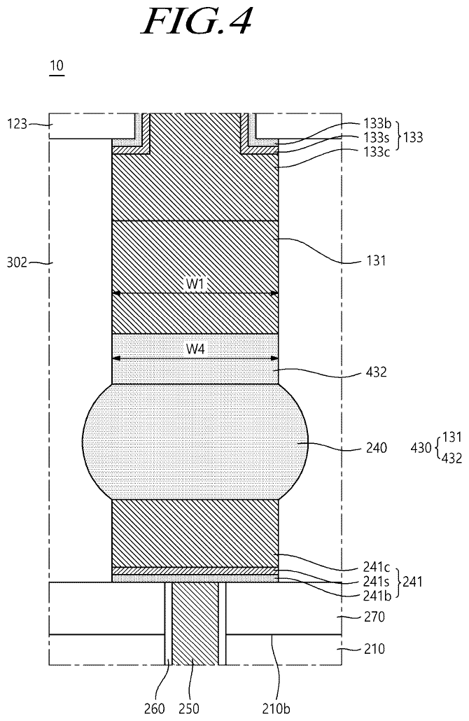

Referring to FIG. 4, a first front conductive bump 430 may be disposed under the first front pad 133. The first front conductive bump 430 may include the first bump pillar 131 and a first solder layer 432. The lower surface of the first bump pillar 131 may contact the upper surface of the first solder layer 432. The first solder layer 432 may be connected to the first bump pillar 131.

In an embodiment, the side surface of the first solder layer 432 may be substantially the same plane as the side surface of the first bump pillar 131. In an embodiment, the width W4 of the first solder layer 432 may be substantially the same as the width W1 of the first bump pillar 131.

The second back conductive bump 240 may be connected to the first front conductive bump 430. The upper surface of the second back conductive bump 240 may contact the lower surface of the first solder layer 432. In an embodiment, the width of the upper surface of the second back conductive bump 240 may be the same as the width of the lower surface of the first solder layer 432. Alternatively, in another embodiment, the width of the upper surface of the second back conductive bump 240 may be different from the width of the lower surface of the first solder layer 432. The second back conductive bump 240 may include the same material as the material forming the first solder layer 432.

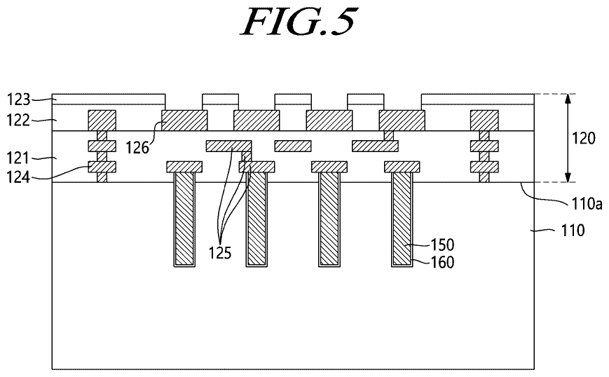

FIGS. 5 to 23 are drawings illustrating a manufacturing method of a semiconductor package according to embodiments of the present disclosure.

Referring to FIG. 5, there may be provided a substrate 110 having a first wiring structure 120 on a first surface 110a. The first wiring structure 120 may include a first circuit insulating layer 121, wirings 125, a guard ring 124, a first chip pad 126, and a first protective insulating layer 122 and 123. A first through-electrode 150 may be provided to pass through the first substrate 110 in a vertical direction and contact the wirings 125. As illustrated in FIG. 5, a first spacer 160 may be provided on a side surface of the first through-electrode 150.

The first substrate 110 may include a semiconductor substrate such as a silicon wafer or a silicon-on-insulator (SOI) wafer. The first substrate 110 may include an III-V group semiconductor substrate, for example, a compound semiconductor substrate such as GaAs. The first substrate 110 may include single crystal silicon, polysilicon, amorphous silicon, single crystal silicon germanium, polycrystalline silicon germanium, carbon-doped silicon, or a combination thereof.

The wirings 125 and the guard ring 124 may be provided within the first circuit insulating layer 121. The guard ring 124 may include a plurality of conductive layers arranged in the same layer as the wirings 125 and the first chip pad 126.

A process of forming the first protective insulating layer 122 and 123 may include a thin film forming process and a patterning process.

The first circuit insulating layer 121 may be a single layer or two or more layers. The first circuit insulating layer 121 may include at least two selected from the group consisting of silicon (Si), oxygen (O), nitrogen (N), carbon (C), and boron (B). The first circuit insulating layer 121 may include silicon oxide, silicon nitride, silicon oxynitride, silicon carbon nitride (SiCN), silicon oxycarbon nitride (SiOCN), a low-k dielectric material, a high-k dielectric material, or a combination thereof.

Each of the wirings 125, the guard ring 124, the first chip pad 126, and the first through-electrode 150 may include, for example, a metal, a metal silicide, a metal nitride, a metal oxide, polysilicon, conductive carbon, or a combination thereof. Each of the wirings 125, the guard ring 124, the first chip pad 126, and the first through-electrode 150 may include tungsten (W), tungsten nitride (WN), titanium (Ti), titanium nitride (TiN), tantalum (Ta), tantalum nitride (TaN), cobalt (Co), nickel (Ni), silver (Ag), platinum (Pt), ruthenium (Ru), gold (Au), aluminum (Al), copper (Cu), tin (Sn), or a combination thereof. In an embodiment, the first chip pad 126 may include aluminum (Al).

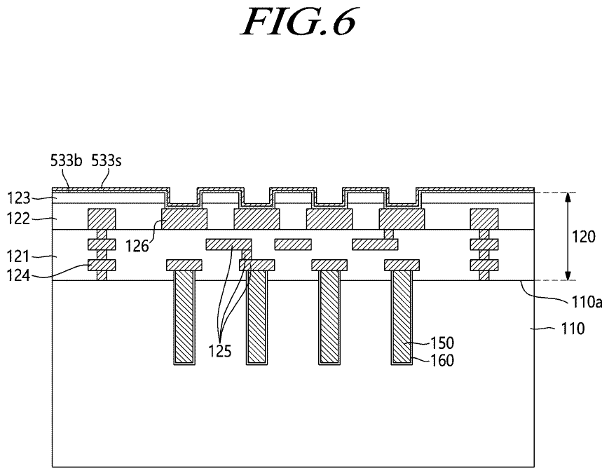

Referring to FIG. 6, a first barrier material layer 533b and a first seed material layer 533s may be sequentially formed on a first wiring structure 120. The first barrier material layer 533b may be in direct contact with the first chip pad 126. The first barrier material layer 533b may include titanium (Ti), titanium tungsten (TiW), titanium nitride (TiN), tantalum (Ta), tantalum nitride (TaN), or a combination thereof. The first seed material layer 533s may include copper (Cu).

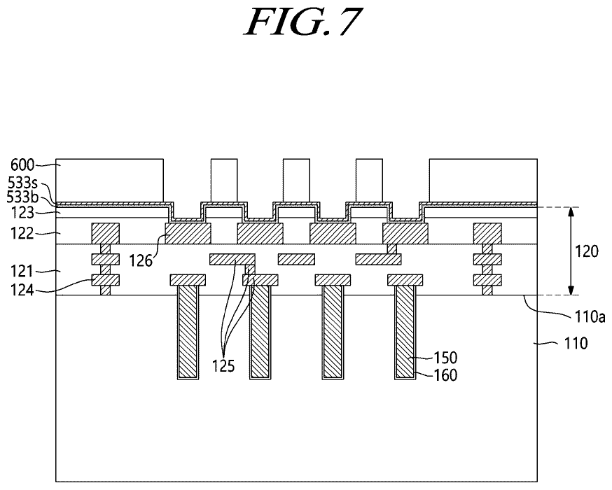

Referring to FIG. 7, a mask pattern 600 may be formed on the first seed material layer 533s. The mask pattern 600 may include a photoresist. The mask pattern 600 may expose a portion of the first seed material layer 533s that overlaps with the first chip pad 126.

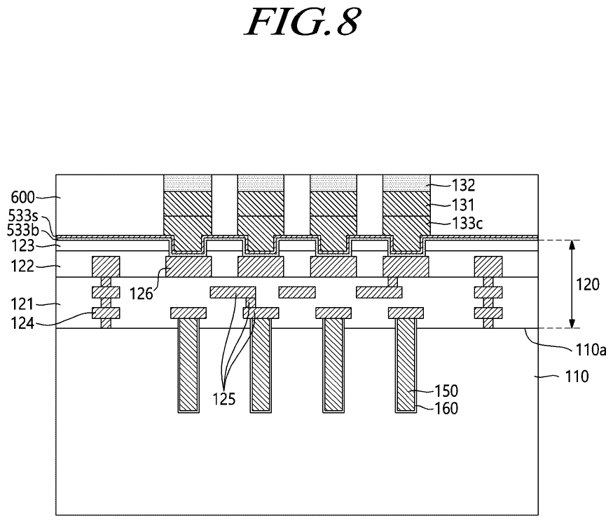

Referring to FIG. 8, a first front conductive layer 133c, a first bump pillar 131, and a first solder layer 132 may be sequentially formed on the first seed material layer 533s in an area where the mask pattern 600 is not formed. The first front conductive layer 133c may include, for example, a metal, a metal nitride, or a combination thereof. The first front conductive layer 133c may include copper (Cu), tungsten (W), tungsten nitride (WN), titanium (Ti), titanium tungsten (TiW), titanium nitride (TiN), tantalum (Ta), tantalum nitride (TaN), cobalt (Co), nickel (Ni), silver (Ag), platinum (Pt), ruthenium (Ru), gold (Au), aluminum (Al), tin (Sn), or a combination thereof. In an embodiment, the first front conductive layer 133c may include a copper layer formed using an electro-plating method. The first bump pillar 131 may include copper. The first solder layer 132 may include copper, nickel, tin, silver, or a combination thereof.

The upper surface of the first solder layer 132 is illustrated as being coplanar with the upper surface of the mask pattern 600, but the embodiments are not limited thereto. For example, the first solder layer 132 may protrude above the upper surface of the mask pattern 600.

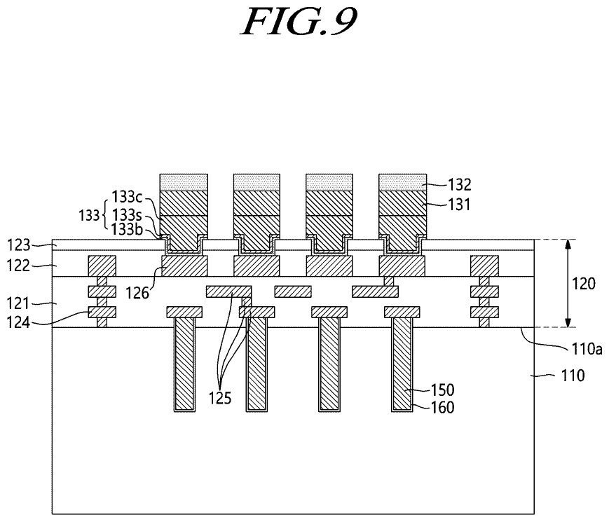

Referring to FIG. 9, the mask pattern 600 may be removed, and the first barrier material layer 533b and the first seed material layer 533s may be partially removed to form a first front pad 133. The first front pad 133 may include a first front barrier layer 133b, a first front seed layer 133s, and a first front conductive layer 133c which are sequentially laminated as illustrated in FIG. 2.

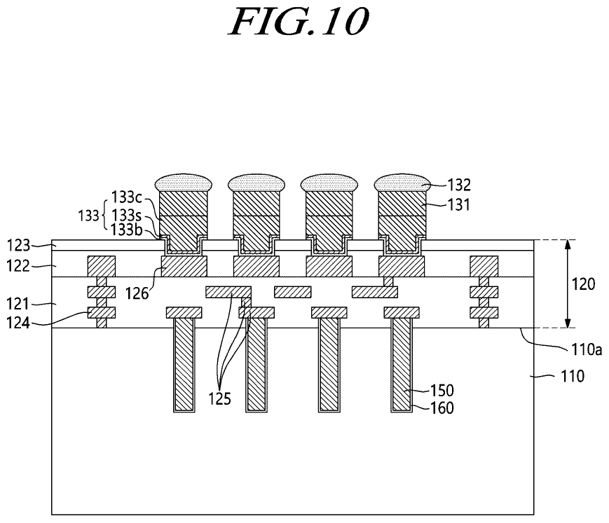

Referring to FIG. 10, there may be performed a reflow process which applies heat to the first solder layer 132. At least a portion of the first solder layer 132 may be melted by the reflow process. In an embodiment, the first solder layer 132 may protrude outward from the side surface of the first bump pillar 131 by the reflow process.

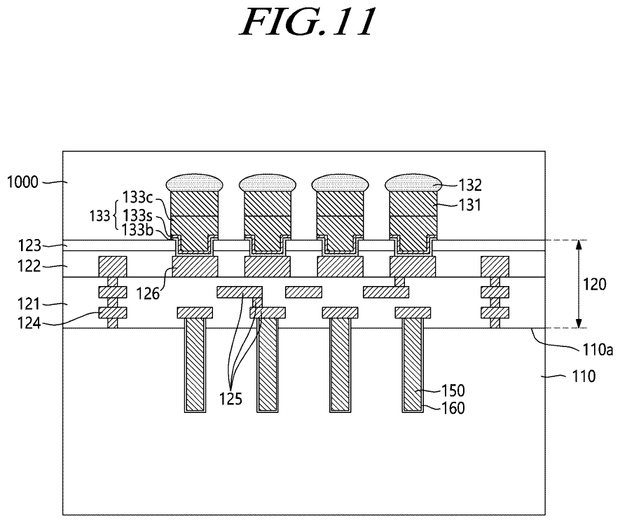

Referring to FIG. 11, a first insulating layer 1000 may be formed on the first wiring structure 120 and the first solder layer 132. The first insulating layer 1000 may be formed at a position higher than the upper surface of the first solder layer 132. The first insulating layer 1000 may include an oxide or a nitride.

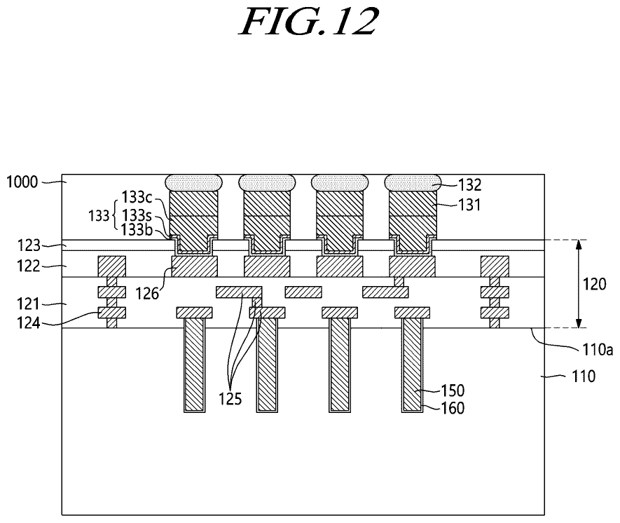

Referring to FIG. 12, at least a portion of the first insulating layer 1000 may be removed. The process of removing at least a portion of the first insulating layer 1000 may include a chemical mechanical polishing (CMP) process. The first insulating layer 1000 may be removed to expose the upper surface of the first solder layer 132.

Thereafter, there may be performed a process of planarizing or flattening an upper surface of the first solder layer 132. The process of planarizing the upper surface of the first solder layer 132 may be performed simultaneously with the process of removing at least a portion of the first insulating layer 1000. In an embodiment, the process of planarizing the upper surface of the first solder layer 132 may include a chemical mechanical polishing CMP process. In an embodiment, after the upper surface of the first solder layer 132 is planarized, the upper surface of the first insulating layer 1000 may form substantially the same plane as the upper surface of the first solder layer 132.

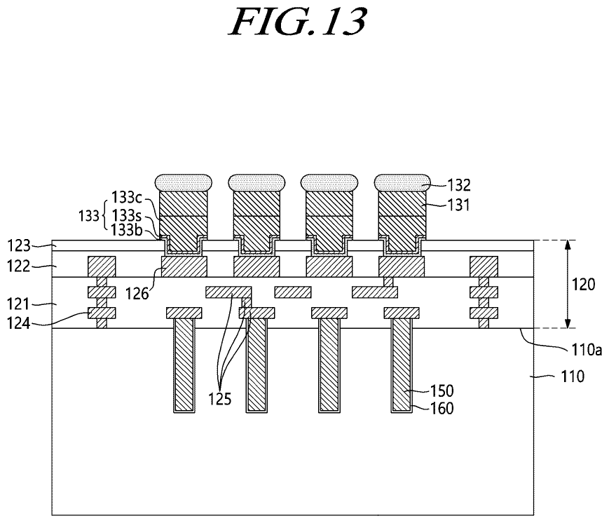

Referring to FIG. 13, the first insulating layer 1000 may be completely removed. The process of removing the first insulating layer 1000 may include, for example, a wet etching process.

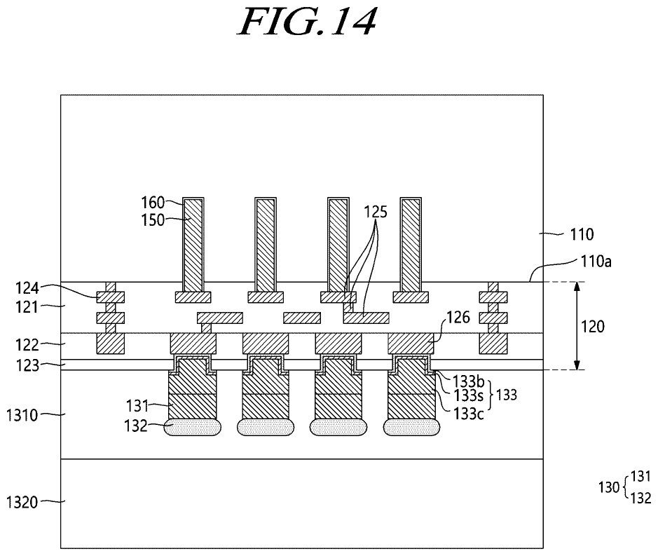

Referring to FIG. 14, there may be loaded a first substrate 110 on which a first front conductive bump 130 and a first front pad 133 are formed on a carrier 1320. A first buffer layer 1310 may be formed between the carrier 1320 and the first front conductive bump 130.

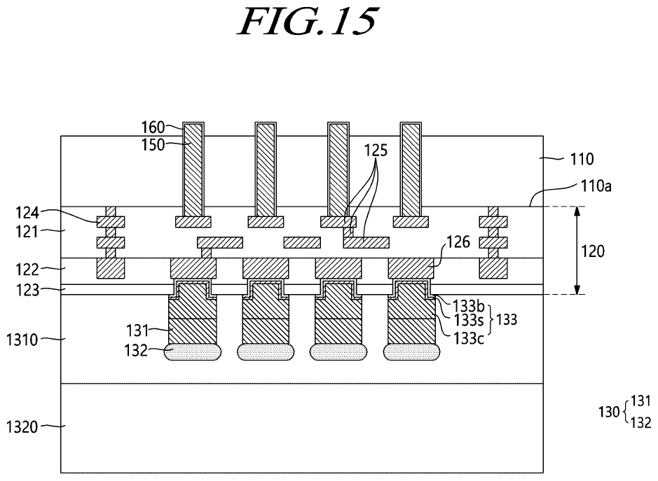

Referring to FIG. 15, the first substrate 110 may be partially removed to expose the first through-electrode 150. One surface of the first substrate 110 may be formed at a position lower than the top of the first through-electrode 150.

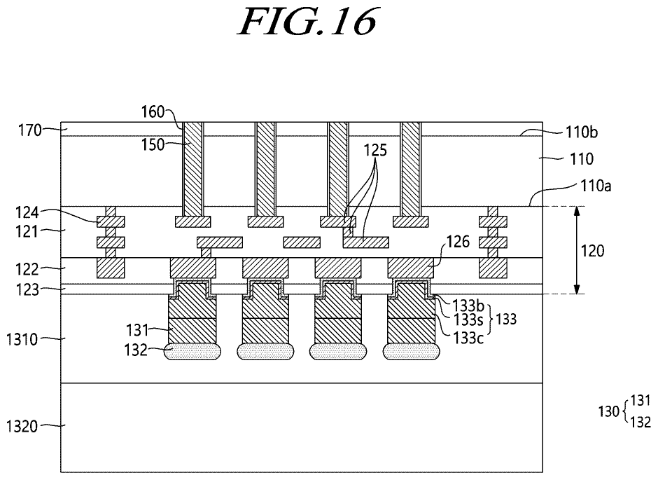

Referring to FIG. 16, a first back insulating layer 170 may be formed on a second surface 110b of the first substrate 110. When the first back insulating layer 170 is formed, the upper surface of the first through-electrode 150 may be exposed. In an embodiment, the upper surface of the first back insulating layer 170 and the upper surface of the first through-electrode 150 may form substantially the same plane.

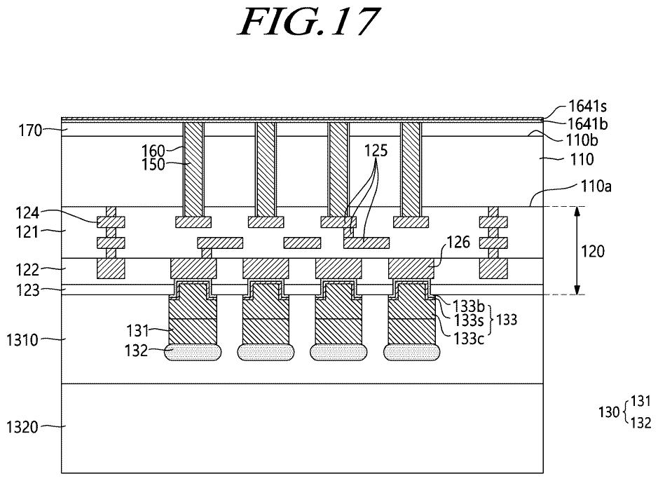

Referring to FIG. 17, a first barrier material layer 1641b and a first seed material layer 1641s may be sequentially formed on the upper surface of the first back insulating layer 170. The first barrier material layer 1641b may include titanium (Ti), titanium tungsten (TiW), titanium nitride (TiN), tantalum (Ta), tantalum nitride (TaN), or a combination thereof. The first seed material layer 1641s may include copper. The first barrier material layer 1641b may include the same material as the first barrier material layer 533b described with reference to FIG. 6. The first seed material layer 1641s may include the same material as the first seed material layer 533s described with reference to FIG. 6.

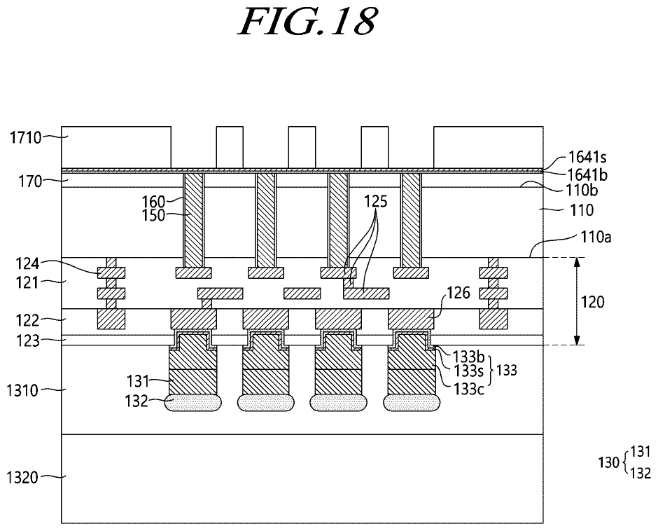

Referring to FIG. 18, a mask pattern 1710 may be formed on the first seed material layer 1641s. The mask pattern 1710 may include the same material as the mask pattern 600 described with reference to FIG. 7. For example, the mask pattern 1710 may include photoresist.

The mask pattern 1710 may expose the upper surface of the first seed material layer 1641s in an area overlapping the area where the first through-electrode 150 is disposed.

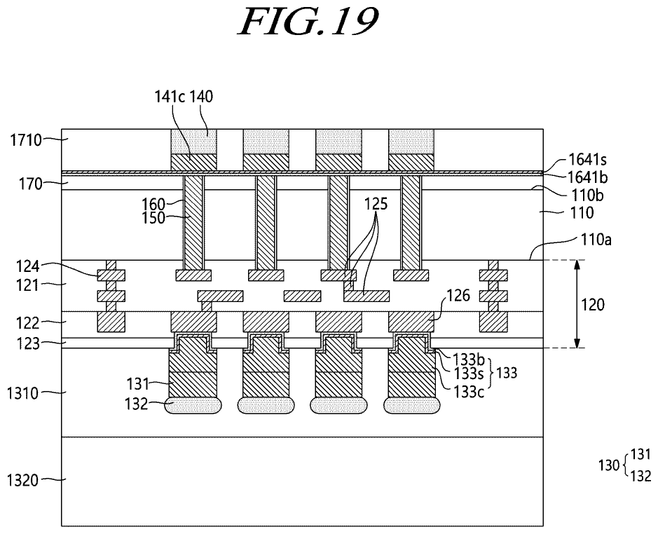

Referring to FIG. 19, a first back conductive layer 141c and a first back conductive bump 140 may be sequentially formed on the first seed material layer 1641s in areas where the mask pattern 1710 is not disposed.

The first back conductive layer 141c may include, for example, a metal, a metal nitride, or a combination thereof. The first back conductive layer 141c may include copper, tungsten, tungsten nitride, titanium, titanium tungsten, titanium nitride, tantalum, tantalum nitride, cobalt, nickel, silver, platinum, ruthenium, gold, aluminum, tin, or a combination thereof. In an embodiment, the first back conductive layer 141c may include a copper layer that is formed using an electrolytic plating method. The first back conductive bump 140 may include the same material as the material forming the first solder layer 132. The first back conductive bump 140 may include copper, nickel, tin, silver, or a combination thereof.

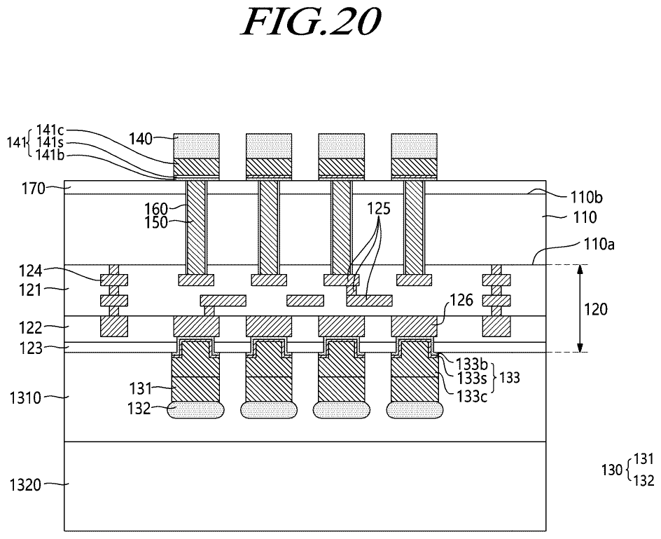

Referring to FIGS. 19 and 20, the mask pattern 1710 may be removed. When the mask pattern 1710 is removed, the first seed material layer 1641s and the first barrier material layer 1641b arranged in an area overlapping the mask pattern 1710 may also be removed together with the mask pattern 1710. The mask pattern 1710, the first seed material layer 1641s, and the first barrier material layer 1641b may be removed to expose an upper surface of the first back insulating layer 170. Removing the mask pattern 1710, the first seed material layer 1641s, and the first barrier material layer 1641b may include an etching process.

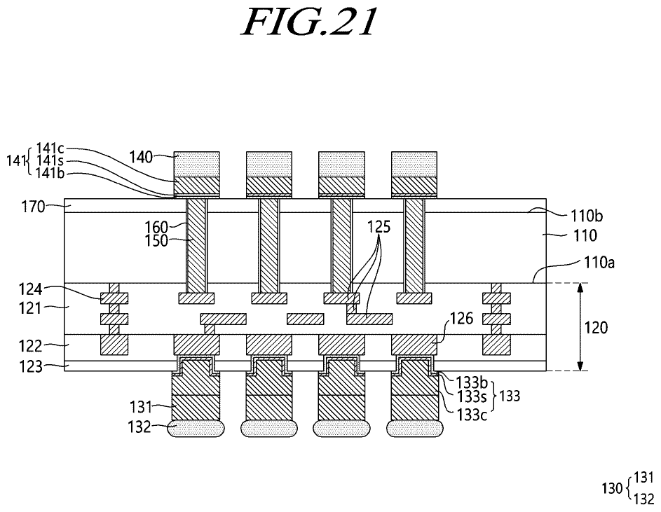

Referring to FIG. 20 and FIG. 21, the carrier 1320 and the first buffer layer 1310 may be removed to expose the first front conductive bump 130, at least a portion of the first front pad 133, and the lower surface of the first protective insulating layer 123. For example, at least a portion of the side surface of the first front conductive layer 133c, the side surface of the first front seed layer 133s, and the side surface of the first front barrier layer 133b may be exposed.

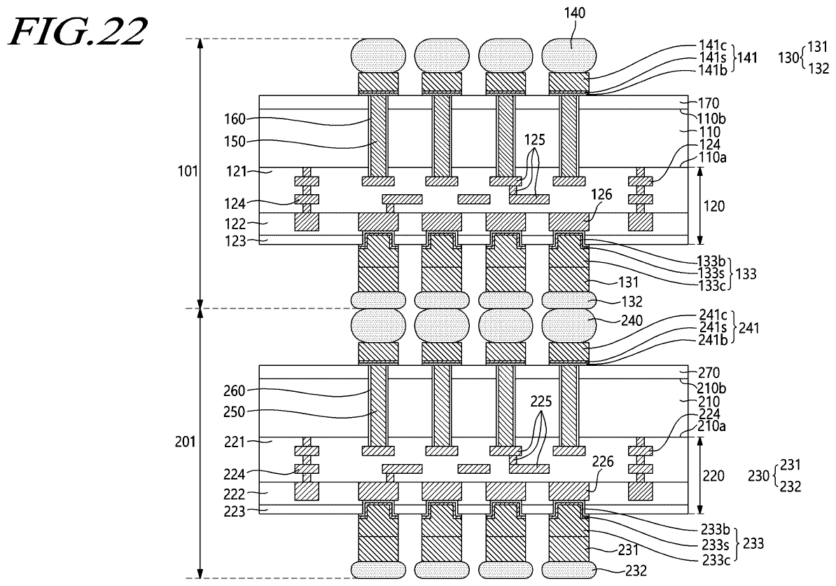

Referring to FIG. 22, a first semiconductor chip 101 may be positioned over a second semiconductor chip 201. For example, the first semiconductor chip 101 may be stacked or laminated on the second semiconductor chip 201.

The process of stacking the first semiconductor chip 101 on the second semiconductor chip 201 may include a reflow process and a compression process. In the reflow process the second back conductive pad 240 is heated so that at least a portion of the second back conductive bump 240 is melted. As at least a portion of the second back conductive bump 240 is melted, the second back conductive bump 240 may have a shape that protrudes outward from the side surface of the second back pad 241. The compression process involves applying pressure to the chips to ensure a solid and reliable connection between them.

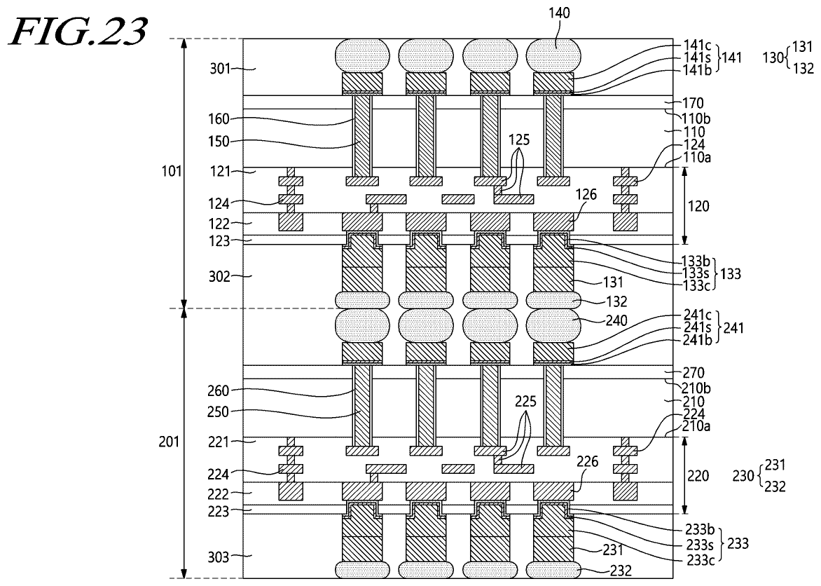

Referring to FIG. 23, the encapsulation layers 301, 302 and 303 may be formed to fill the space between the semiconductor chips. For example, a second encapsulation layer 302 may be formed to fill the space between the first semiconductor chip 101 and the second semiconductor chip 201. The second encapsulation layer 302 may fill the space between the first front conductive bumps 130, the space between the second back conductive bumps 240, the space between the first front pads 133, the space between the second back pads 241, and the space between the second back insulating layer 270 and the first protective layer 123. The encapsulation layers 301, 302 and 303 may include an epoxy molding compound.

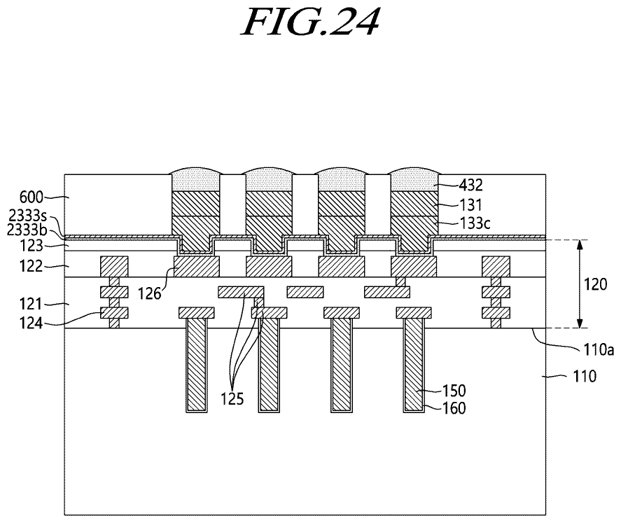

FIGS. 24 to 27 are drawings illustrating other manufacturing methods of a semiconductor package according to embodiments of the present disclosure.

The first substrate 110, the first wiring structure 120, the first through-electrode 150, the first spacer 160, a first barrier material layer 2333b, a first seed material layer 2333s, the first front conductive layer 133c, the first bump pillar 131, the first solder layer 432, and a mask pattern 600 illustrated in FIG. 24 may be formed by substantially the same method as the method for manufacturing a semiconductor package described with reference to FIGS. 5 to 8.

Referring to FIG. 24, a reflow process that applies heat to the first solder layer 432 may be performed. At least a portion of the first solder layer 432 may be melted by the reflow process. The first solder layer 432 may protrude above the upper surface of the mask pattern 600. For example, at least a portion of the first solder layer 432 may cover the upper surface of the mask pattern 600.

As the reflow process progresses, the mask pattern 600 may be hardened, so that the side surface of the first solder layer 432 may not protrude further than the side surface of the first bump pillar 131. In an embodiment, after performing the reflow process, the width of at least a portion of the first solder layer 432 may be substantially the same as the width of the first bump pillar 131. Here, “substantially the same” may include a case where the side surface of the first solder layer 432 slightly protrudes further than the side surface of the first bump pillar 131 due to a process error.

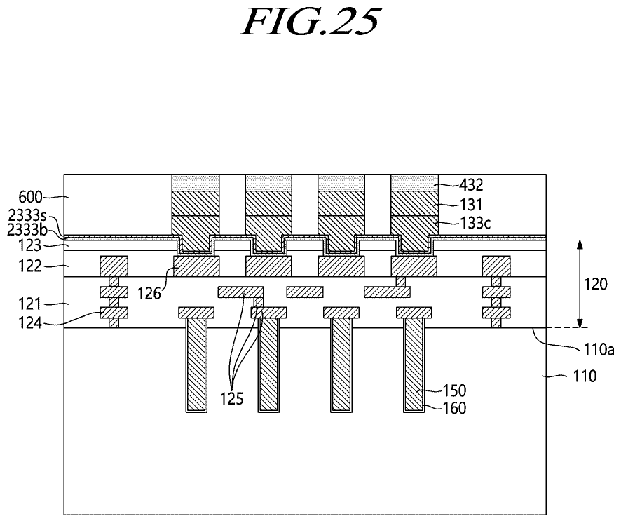

Referring to FIG. 25, a process of planarizing or flattening an upper portion of the first solder layer 432 may be performed. The planarization process may remove a portion of the first solder layer 432 protruding above the upper (e.g., top) surface of the mask pattern 600. The planarization of the upper portion of the first solder layer 432 may include a chemical mechanical polishing process. After the upper portion of the first solder layer 432 is planarized, the upper surface of the first solder layer 432 may form substantially the same plane as the upper surface of the mask pattern 600.

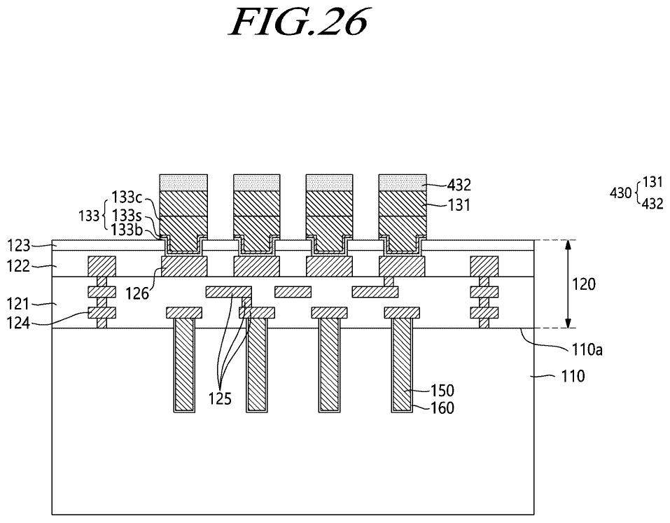

Referring to FIG. 26, the mask pattern 600 may be removed, and the first barrier material layer 2333b and the first seed material layer 2333s are partially removed, so that the first front pad 133 and the first front conductive bump 430 may be formed. The first front pad 133 may include a first front barrier layer 133b, a first front seed layer 133s, and a first front conductive layer 133c that are sequentially stacked as illustrated in FIG. 4. The first front conductive bump 430 may include a first bump pillar 131 and a first solder layer 432.

After the first front conductive bump 430 is formed, a back conductive bump may be formed under the first substrate 110. The back conductive bump may be formed in substantially the same manner as the method for manufacturing a semiconductor package described with reference to FIGS. 14 to 21.

After the back conductive bump is formed, the back conductive bump may be connected to a front conductive bump included in another semiconductor chip and formed in the same manner as the first front conductive bump 130 described with reference to FIGS. 24 to 26.

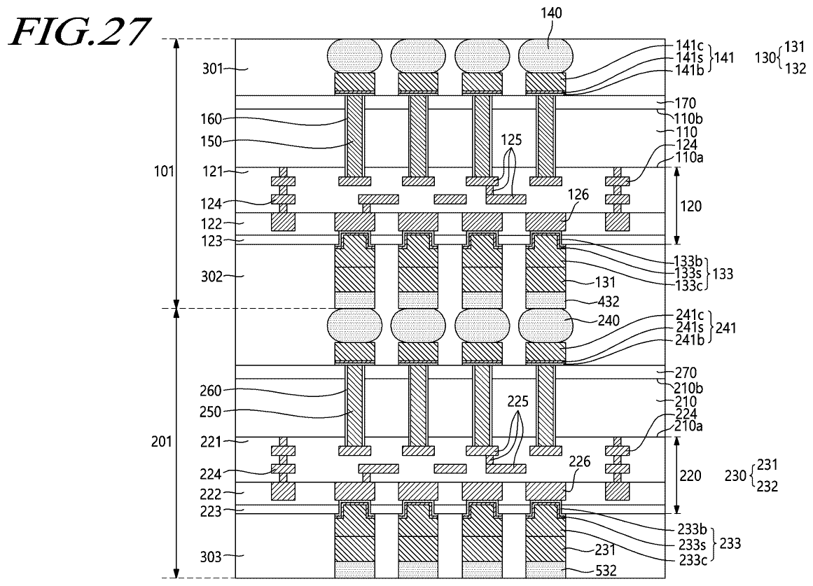

Referring to FIG. 27, a first semiconductor chip 101 may be positioned over a second semiconductor chip 201a. The first semiconductor chip 101 may be stacked on the second semiconductor chip 201.

The process of stacking the first semiconductor chip 101 on the second semiconductor chip 201 may include a process of connecting the first front conductive bump 430 to the second back conductive bump 240 and then performing a reflow process and a compression process. At least a portion of the second back conductive bump 240 may be melted by the reflow process. As at least a portion of the second back conductive bump 240 is melted, the second back conductive bump 240 may have a shape that protrudes outward from the side surface of the second back pad 241.

In an embodiment, the width of the first solder layer 432 may be substantially the same as the width of the first bump pillar 131. In an embodiment, the width of the first solder layer 432 may be less than the width of the second back conductive bump 240 after the reflow process is performed.

Referring again to FIGS. 1 to 3 and FIGS. 10 to 12, a first solder layer 132 may be formed, and a reflow process may be performed to melt at least a portion of the first solder layer 132. After the reflow process, a process of planarizing the upper surface of the first solder layer 132 may be performed. Alternatively, referring again to FIGS. 4 and 24 to 26, a first solder layer 432 may be formed, and a reflow process may be performed to melt at least a portion of the first solder layer 432. After the reflow process, a process of planarizing the upper surface of the first solder layer 432 may be performed.

According to embodiments of the present disclosure, a process of planarizing the upper surface of the front conductive bump may be performed after the reflow process of the front conductive bump. Afterwards, the front conductive bump may be connected to a back conductive bump included in another semiconductor chip. Since a process of planarizing the upper surface of the front conductive bump is performed before connecting the front conductive bump and the back conductive bump, that is, since a part of the front conductive bump is removed, it is possible to prevent a short circuit between adjacent bumps due to an increase in the volume of the bumps during the reflow process.

In addition, since the upper surface of the front conductive bump is planarized, the bonding interface between the bumps may be planarized. In addition, since the size of the front conductive bump is reduced, it is possible to reduce the size of the entire area occupied by the bumps. Therefore, precise bonding and lamination between the semiconductor chips may be achieved.

The above description and the accompanying drawings provide the technical concepts of the present disclosure for illustrative purposes only. Various modifications, additions and substitutions to the described embodiments will be readily apparent to those skilled in the art without departing from the spirit and scope of the present disclosure. In addition, since the embodiments disclosed in this disclosure are not intended to limit the technical concepts of this disclosure but to describe the technical concepts of this disclosure, the scope of the technical concepts of this disclosure is not limited by these embodiments. The protection scope of this disclosure should be interpreted by the claims below, and all technical concepts within the equivalent scope should be interpreted as being included in the scope of this disclosure. Furthermore, the embodiments may be combined to form additional embodiments.

What is claimed is:

1. A manufacturing method of a semiconductor package, the manufacturing method comprising:
forming a through-electrode in a substrate, the substrate including a first surface and a second surface opposite to each other;
forming a front conductive bump on the first surface of the substrate;
reflowing the front conductive bump; and
planarizing an upper portion of the front conductive bump after reflowing the front conductive bump.

2. The manufacturing method of claim 1, further comprising forming a first insulating layer to cover the front conductive bump between reflowing the front conductive bump and planarizing the upper portion of the front conductive bump.

3. The manufacturing method of claim 2, wherein an upper surface of the first insulating layer and an upper surface of the front conductive bump form substantially the same plane by planarizing the upper portion of the front conductive bump.

4. The manufacturing method of claim 2, further comprising removing the first insulating layer after planarizing the upper portion of the front conductive bump.

5. The manufacturing method of claim 1, wherein the front conductive bump includes a bump pillar and a solder layer connected to the bump pillar,
wherein planarizing the upper portion of the front conductive bump includes planarizing an upper portion of the solder layer.

6. The manufacturing method of claim 5, wherein a maximum width of the solder layer is greater than a width of the bump pillar.

7. The manufacturing method of claim 5, wherein a maximum width of the solder layer is substantially equal to a width of the bump pillar.

8. The manufacturing method of claim 1, further comprising:
forming a back conductive bump connected to the through-electrode on the second surface of the substrate; and
reflowing the back conductive bump.

9. The manufacturing method of claim 1, wherein forming the front conductive bump comprises:
forming a mask pattern on the first surface of the substrate; and
forming a conductive material in an area excluding an area where the mask pattern is disposed.

10. The manufacturing method of claim 9, wherein an upper surface of the mask pattern and an upper surface of the front conductive bump form substantially the same plane by planarizing the upper portion of the front conductive bump.

11. The manufacturing method of claim 9, further comprising removing the mask pattern after planarizing the upper portion of the front conductive bump.

12. The manufacturing method of claim 9, further comprising:
forming a back conductive bump connected to the through-electrode on the second surface of the substrate; and
reflowing the back conductive bump.

13. A manufacturing method of a semiconductor package, the manufacturing method comprising:
forming a first front conductive bump on a first surface of a first semiconductor chip, the first semiconductor chip further including a second surface opposite to the first surface;
reflowing the first front conductive bump;
planarizing an upper portion of the first front conductive bump after reflowing the first front conductive bump;
forming a second back conductive bump on a second surface of a second semiconductor chip including a first surface and the second surface opposed to each other and stacked below the first surface of the first semiconductor chip; and
connecting the second back conductive bump to the first front conductive bump after planarizing the upper portion of the first front conductive bump.

14. The manufacturing method of claim 13, further comprising forming a first insulating layer to cover the first front conductive bump between reflowing the first front conductive bump and planarizing the upper portion of the first front conductive bump.

15. The manufacturing method of claim 14, wherein an upper surface of the first insulating layer and an upper surface of the first front conductive bump form substantially the same plane by planarizing the upper portion of the first front conductive bump.

16. The manufacturing method of claim 14, further comprising removing the first insulating layer after the planarizing the upper portion of the first front conductive bump.

17. The manufacturing method of claim 13, wherein forming the first front conductive bump comprises:
forming a mask pattern on the first surface of the first semiconductor chip; and
forming a conductive material in an area excluding an area where the mask pattern is disposed.

18. The manufacturing method of claim 17, wherein an upper surface of the mask pattern and an upper surface of the first front conductive bump form substantially the same plane by planarizing the upper portion of the first front conductive bump.

19. The manufacturing method of claim 17, further comprising removing the mask pattern after planarizing the upper portion of the first front conductive bump.

20. A manufacturing method for making a semiconductor package, the method comprising:
providing a first semiconductor chip including first and second surfaces opposite to each other;
providing a second semiconductor chip including first and second surfaces opposite to each other;
forming a first front conductive bump on the first surface of the semiconductor chip;
forming a second back conductive bump on the second surface of the second semiconductor chip;
reflowing and planarizing the upper portion of the first front conductive bump; and
stacking the second semiconductor chip below the first surface of the first semiconductor chip so that the second back conductive bump contacts the first front conductive bump after planarizing the upper portion of the first front conductive bump.
